(19) United States
(12) Patent Application Publication
(10) Pub. No.: US 2024/0404836 A1
(43) Pub. Date: Dec. 5, 2024

(54) METHOD FOR PRODUCING VERTICAL POWER TRANSISTORS AND VERTICAL POWER TRANSISTOR

(71) Applicant: Robert Bosch GmbH, Stuttgart (DE)

(72) Inventors: Jens Baringhaus, Sindelfingen (DE); Kevin Dannecker, Reutlingen (DE)

(21) Appl. No.: 18/674,169

(22) Filed: May 24, 2024

(30) Foreign Application Priority Data
May 31, 2023 (DE) 10 2023 205 073.0

(51) Int. Cl. H01L 21/308; H01L 21/3065

(52) U.S. Cl. CPC H01L 21/3088; H01L 21/3065; H01L 21/3081; H01L 21/3085; H01L 21/3086

(57) ABSTRACT

A method for producing vertical power transistors. The method includes: applying a dielectric layer to a semiconductor material; applying a first photoresist layer to the dielectric layer; creating first openings having a first width in the first photoresist layer exposing first regions of the dielectric layer; etching the first regions of the dielectric layer to at least a specified depth of the dielectric layer such that a first structured dielectric layer is created; removing the first photoresist layer; applying a second photoresist layer to the first structured dielectric layer; creating second openings having a second width in the second photoresist layer exposing second regions of the dielectric layer; etching the second regions of the dielectric layer up to a surface of the semiconductor material such that a second structured dielectric layer is created; removing the second photoresist layer; and creating the first trenches and the second trenches.

### FIELD

The present invention relates to a method for producing vertical power transistors and a vertical power transistor.

### BACKGROUND INFORMATION

The production of vertical power transistors requires the etching of trenches. The width of the trenches can be easily varied using a corresponding mask layout. Structure sizes smaller than 2 μm are usually produced by means of plasma etching. The etching rate is determined by the width of the trenches. The wider the trench, the higher the etching rate. The trenches have a difference in depth of between 10% and 20%. This is subject to process fluctuations and is difficult to control or difficult to reproduce. Therefore, a large number of lithography and etching steps is necessary to produce trenches of different trench depths. This is time-consuming and costly.

An object of the present invention is to overcome these disadvantages.

### SUMMARY

The method according to an example embodiment of the present invention for producing vertical power transistors having at least first trenches having a first trench depth and at least second trenches having a second trench depth, wherein the first trenches and the second trenches are arranged alternately laterally at a distance from one another and the first trench depth and the second trench depth have a difference of at least 30%, comprises applying a dielectric layer to a semiconductor material and applying a first photoresist layer to the dielectric layer. The method further comprises creating first openings having a first width in the first photoresist layer with the aid of first photolithography, wherein first regions of the dielectric layer are exposed, etching the first regions of the dielectric layer to at least a specified depth of the dielectric layer such that a first structured dielectric layer is created, and removing the first photoresist layer. The method further comprises applying a second photoresist layer to the first structured dielectric layer, creating second openings having a second width in the second photoresist layer with the aid of second photolithography, wherein second regions of the dielectric layer are exposed, and etching the second regions of the dielectric layer to a surface of the semiconductor material such that a second structured dielectric layer is created. The method further comprises removing the second photoresist layer and creating the first trenches and the second trenches starting from the second structured dielectric layer into the semiconductor material with the aid of a further etching step.

An advantage here is that vertical power transistors having controllable, large trench depths can be produced.

In a further development of the present invention, a marking layer is created within the dielectric layer, which marking layer identifies the specified depth of the dielectric layer.

An advantage here is that the specified depth is independent of the dielectric layer thickness.

In a further configuration of the present invention, the first width and the second width are the same size.

The advantage here is that trenches having different depths can be produced despite the same width.

The further method according to an example embodiment of the present invention for producing vertical power transistors having at least first trenches having a first trench width and at least second trenches having a second trench width, wherein the first trench depth and the second trench depth have a difference of at least 30%, comprises applying a dielectric layer to a semiconductor material and applying a photoresist layer to the dielectric layer. The method further comprises creating first openings having a first width and second openings having a second width in the photoresist layer by means of photolithography, wherein the first openings and the second openings are arranged alternately laterally at a distance from one another, wherein the first width and the second width are different in size and the first openings expose first regions of the dielectric layer and the second openings expose second regions of the dielectric layer, etching the first regions and the second regions such that a structured dielectric layer is created and creating the first trenches and the second trenches starting from the structured dielectric layer into the semiconductor material with the aid of a further etching step.

An advantage here is that the production of the vertical power transistor is cost-effective.

In a further development of the present invention, the semiconductor material comprises Si, SiC or GaN.

In a further configuration of the present invention, the dielectric layer comprises SiN or SiO₂.

An advantage here is that the dielectric layer is of high quality.

According to an example embodiment of the present invention, the vertical power transistor comprises a semiconductor material, at least first trenches having a first trench depth and second trenches having a second trench depth. According to the present invention, the first trench depth and the second trench depth have a difference of at least 30%.

An advantage here is that the cell size is small and the breakdown field strength is high.

In a further development of the present invention, the semiconductor material comprises Si, SiC or GaN.

Further advantages of the present invention can be found in the following description of exemplary embodiments and in the rest of the disclosure herein.

### BRIEF DESCRIPTION OF THE DRAWINGS

The present invention is explained below with reference to preferred embodiments and the figures.

FIG. 1 shows a method according to an example embodiment of the present invention for producing a vertical power transistor,

FIG. 2 shows a further method according to an example embodiment of the present invention for producing a vertical power transistor.

FIG. 3 shows an intermediate result of the method according to the present invention after performing step 110.

### DETAILED DESCRIPTION OF EXAMPLE EMBODIMENTS

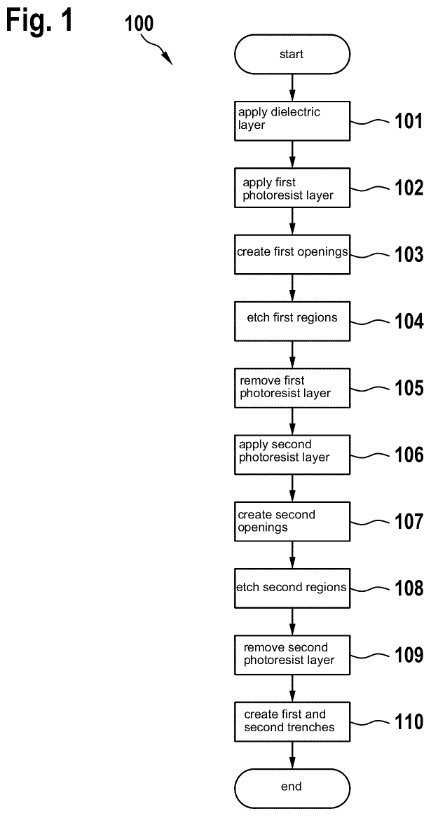

FIG. 1 shows a method 100 according to the present invention for producing a vertical power transistor having at least first trenches having a first trench depth and at least second trenches having a second trench depth, wherein the first trenches and the second trenches are arranged alternately laterally at a distance from one another and the first trench depth and the second trench depth have a difference of at least 30%. The method 100 starts with a step 101 in which a dielectric layer is applied to a semiconductor material. The semiconductor material comprises, for example, Si, SiC or GaN and the dielectric layer comprises SiN or SiO. In a subsequent step 102, a first photoresist layer is applied to the dielectric layer. In a subsequent step 103, first openings having a first width are created in the first photoresist layer with the aid of first photolithography. This exposes the first regions of the dielectric layer. In a subsequent step 104, the first regions of the dielectric layer are etched to at least a specified depth of the dielectric layer. This structures the dielectric layer or creates a first structured dielectric layer. Alternatively, the dielectric layer below the first openings can be removed completely. The structured first photoresist layer serves as a protective mask for parts of the dielectric layer that are to be etched in a later step. The shallower trenches are defined with the aid of the first openings. In a subsequent step 105, the first photoresist layer is removed. In a subsequent step 106, a second photoresist layer is applied to the first structured dielectric layer. In a subsequent step 107, second openings having a second width are created in the second photoresist layer with the aid of second photolithography. This exposes the second regions of the dielectric layer. In a subsequent step 108, the second regions of the dielectric layer are etched up to a surface of the semiconductor material. This creates a second structured dielectric layer. In other words, the surface of the semiconductor material is exposed in certain regions. The second openings define the dimensions of the deeper trenches. In a subsequent step 109, the second photoresist layer is removed. In a subsequent step 110, the first trenches and the second trenches are created with the aid of a further etching step. The etching steps 104, 108 and 110 are carried out by means of plasma etching, for example. If the dielectric layer has been removed to a specified depth in step 104, the etching of the semiconductor material for the first trenches starts with a time delay, since there are parts of the hard mask, i.e. residues of the dielectric layer, below the first openings, which must be removed by means of the same etching step 110. The selectivity of the hard mask, i.e. the first structured dielectric layer, and the specified depth determine the difference in depth of the trenches. Thus, the trench width and trench depth are decoupled from one another.

Alternatively, steps 106 to 109 can be performed after the dielectric layer has been applied in step 101 and steps 103 to 105 can be performed afterwards, such that the deeper trenches are defined first and subsequently the shallower trenches.

In one exemplary embodiment, a marking layer is created within the dielectric layer during step 101. Initially, the material for the dielectric layer is deposited on the semiconductor material up to a specified height, for example SiN or SiO₂. A marking layer made of a different material is subsequently deposited on the dielectric layer. The marking layer comprises polysilicon, for example, and has a thickness of 20 nm. Alternatively, SiN can be used as a marking layer for a dielectric layer made of SiO₂, i.e. a SiO₂ hard mask. SiO₂ can be used as a marking layer for a SiN hard mask. The marking layer has a thickness of between 20 nm and 100 nm. The deposition of the material for the dielectric layer is subsequently continued until the desired thickness of the dielectric layer is achieved. Alternatively, the etching step 104 can be performed in a time-coupled manner, such that the etching is stopped within the dielectric layer.

Additionally or alternatively, the first width and the second width are the same size. This means that, with this method, trenches of the same width but different depths can be produced.

The vertical power transistor is subsequently finished with processes from the related art.

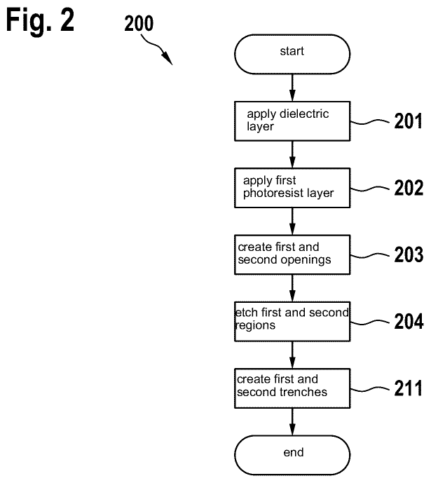

FIG. 2 shows a further method 200 according to the present invention for producing vertical power transistors having at least first trenches having a first trench depth and at least second trenches having a second trench depth, wherein the first trench depth and the second trench depth have a difference of at least 30%. The method 200 starts with a step 201 in which a dielectric layer is applied to a semiconductor material. The semiconductor material comprises, for example, Si, SiC or GaN and the dielectric layer comprises SiN or SiO₂. In a subsequent step 202, a first photoresist layer is applied to the dielectric layer. In a subsequent step 203, first openings having a first width and second openings having a second width are created in the photoresist layer by means of photolithography, wherein the first width and the second width are of different sizes. The first openings and the second openings are arranged alternately laterally at a distance from one another, wherein the first openings expose first regions and the second openings expose second regions of the dielectric layer. In other words, the first openings and the second openings are created simultaneously in one step. In a subsequent step 204, the first regions and the second regions of the dielectric layer are etched. This creates a structured dielectric layer, wherein the first width is narrower than the second width, for example, such that the surface of the semiconductor material is exposed below the second openings, whereas there is still dielectric material below the first openings. This is due to the lower etching rate of the narrower openings or width. In a subsequent step 211, the first trenches and the second trenches are created starting from the structured dielectric layer and extending into the semiconductor material with the aid of a further etching step. The etching of the semiconductor material starts with a time delay for the first trenches, since there are parts of the hard mask underneath the first openings that have to be removed by means of the same etching step 211. The difference in depth between the trenches is determined by the selectivity of the hard mask or the structured dielectric layer together with the residues of the hard mask below the first openings in relation to the semiconductor material to be etched and the different widths of the trenches. The trench width and trench depth are coupled together in this further method according to the present invention, wherein a significant difference in depth of the trenches can be created with a single lithography step, which can be controlled.

The vertical power transistor is subsequently finished with processes from the related art.

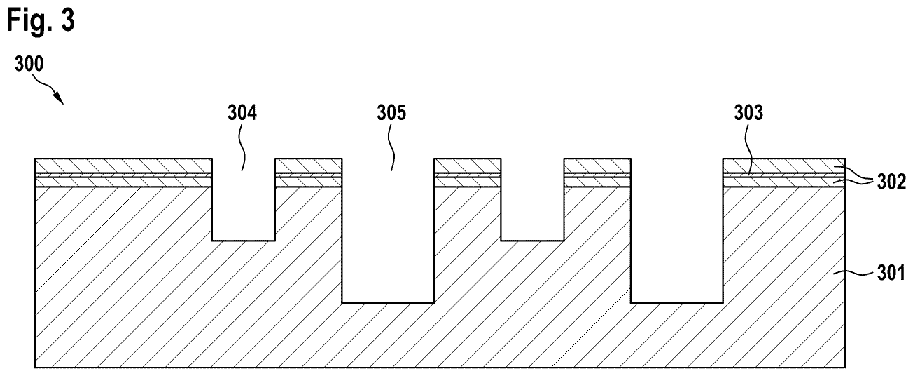

FIG. 3 shows an intermediate result 300 of the method according to the present invention for producing a vertical power transistor after performing step 111 in FIG. 1. A semiconductor material 301 to which a dielectric layer 302 is applied is shown. A marking layer 303 is arranged within the dielectric layer 302 in this exemplary embodiment. Starting from a surface of the dielectric layer 302, the first trenches 304 and the second trenches 305 extend into the semiconductor material 301. The semiconductor material 301 comprises, for example, Si, SiC or GaN.

Alternatively, and not shown in FIG. 3, the marking layer 303 can be dispensed with, such that the dielectric layer 302 is arranged in one piece on the semiconductor material 301.

The present invention is not limited to two different trench depths. A variety of trenches with different trench depths can be created.

A vertical power transistor having trenches of different depths is used, for example, in the electric drive train of an electric or hybrid vehicle, for example in a DC/DC converter or inverter, as well as in vehicle charging devices.

1-8. (canceled)

9. A method for producing vertical power transistors having at least first trenches having a first trench depth and at least second trenches having a second trench depth, wherein the first trenches and the second trenches are arranged alternately laterally at a distance from one another, and the first trench depth and the second trench depth have a difference of at least 30%, the method comprising the following steps:
applying a dielectric layer to a semiconductor material;
applying a first photoresist layer to the dielectric layer;
creating first openings having a first width in the first photoresist layer using first photolithography, wherein first regions of the dielectric layer are exposed by the first openings;
etching the first regions of the dielectric layer to at least a specified depth of the dielectric layer such that a first structured dielectric layer is created;
removing the first photoresist layer;
applying a second photoresist layer to the first structured dielectric layer;
creating second openings having a second width in the second photoresist layer using second photolithography, wherein second regions of the dielectric layer are exposed by the second openings;
etching the second regions of the dielectric layer up to a surface of the semiconductor material such that a second structured dielectric layer is created;
removing the second photoresist layer; and
creating the first trenches and the second trenches starting from the second structured dielectric layer into the semiconductor material using a further etching step.

10. The method according to claim 9, wherein a marking layer is created within the dielectric layer, the marking layer identifying a depth of the dielectric layer.

11. The method according to claim 9, wherein the first width and the second width are the same size.

12. A method for producing vertical power transistors having at least first trenches having a first trench depth and at least second trenches having a second trench depth, wherein the first trench depth and the second trench depth have a difference of at least 30%, the method comprising the following steps:
applying a dielectric layer to a semiconductor material;
applying a photoresist layer to the dielectric layer;
creating first openings having a first width and second openings having a second width in the photoresist layer using photolithography, wherein the first openings and the second openings are arranged alternately laterally at a distance from one another, wherein the first width and the second width are different in size, and the first openings expose first regions of the dielectric layer and the second openings expose second regions of the dielectric layer;
etching the first regions and the second regions of the dielectric layer such that a structured dielectric layer is created; and
creating the first trenches and the second trenches starting from the structured dielectric layer into the semiconductor material using a further etching step.

13. The method according to claim 9, wherein the semiconductor material includes Si or SiC or GaN.

14. The method according to claim 9, wherein the dielectric layer comprises SiN or SiO₂.

15. A vertical power transistor, comprising:
a semiconductor material; and
at least first trenches having a first trench depth and at least second trenches having a second trench depth, wherein the first trench depth and the second trench depth have a difference of at least 30%.

16. The vertical power transistor according to claim 15, wherein the semiconductor material includes Si or SiC or GaN.
